(19) United States
(12) Patent Application Publication
(10) Pub. No.: US 2011/0007463 A1
(43) Pub. Date: Jan. 13, 2011

(54) ELECTRONIC DEVICE COVER

(76) Inventor: Frank J. Hodges, Yorba Linda, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 12/833,904

(22) Filed: Jul. 9, 2010

Related U.S. Application Data
(60) Provisional application No. 61/224,840, filed on Jul. 10, 2009.

(51) Int. Cl. H05K 7/00

(52) U.S. Cl. 361/679.01

(57) ABSTRACT

A cover can be provided for an electronic device such as a remote control or an electronic key fob. The cover can be used to personalize, repair, and/or increase the life of the electronic device, among other benefits.

### CROSS-REFERENCE TO RELATED APPLICATIONS

This application claims the benefit of priority under 35 U.S.C. §119(e) of U.S. Provisional Application No. 61/224,840, filed Jul. 10, 2009, entitled “ELECTRONIC DEVICE COVER,” which is hereby incorporated herein by reference in its entirety and is to be considered a part of this specification.

### BACKGROUND OF THE INVENTION

1. Field of the Invention

The present invention relates generally to product covers and specifically to covers for electronic devices.

2. Description of the Related Art

There are many different types of electronic devices, including remote controls. Some remote controls are used for controlling appliances, such as TV, audio and video equipment, air conditioning/heating control units, etc. Some others are used to access the interior of, or actuate functions in, an automobile. The remote controls for automobiles are commonly included in key ring fobs.

A key fob is a decorative and/or useful item typically carried with keys on a ring or a chain. It can also be carried in a purse, a pocket, etc. together with or separate from keys.

Key fobs vary considerably in size, style and functionality. They can include simple discs of smooth metal or plastic, typically with a message or symbol such as that of a logo or a sign of a group affiliation. Other examples of key fobs include small tools such as flashlights, compasses, calculators, penknives, discount cards, bottle openers, and USB flash drives. Miniature key fob versions of larger electronic devices are also common, such as digital photo frames and simple video games.

Other electronic key fobs include remote keyless entry systems and remote keyless ignition systems on motor vehicles, remotes for car alarms, garage door openers, etc. Electronic key fobs can also be used in settings such as apartment buildings and condominium buildings for access to common areas (i.e. lobby doors, storage areas, fitness room, pool, etc.). The electronic key fob can operate in much the same manner as a proximity card to communicate (via a reader pad) with a central server for the building, which can be programmed to allow access only to those areas in which the tenant or owner is permitted to access, or only within certain time frames.

An electronic key fob can include buttons dedicated to perform certain functions. For example, a remote keyless entry system for a car may include buttons for locking or unlocking the doors, opening the trunk, and a panic button for activating a car alarm or horn. Electronic key fobs may not have any buttons or they may have one or more buttons. For example, some electronic key fobs may not have any buttons and may activate some other electronic device based on proximity to the device or some other sensor.

Electronic key fobs are also used in computer networks and systems. For example, a user may have an electronic key fob that provides one part of a three way match to log in over an unsecure network connection to a secure network. This kind of electronic key fob may have a keypad on which the user must enter a PIN in order to retrieve an access code, or it could be a display-only device such as a VPN token that algorithmically generates security codes as part of a challenge/response authentication system.

### SUMMARY OF THE INVENTION

A cover can be provided for an electronic device such as a remote control or an electronic key fob. In some embodiments, the cover can be used to personalize, repair, and/or increase the life of the electronic device, among other benefits.

### BRIEF DESCRIPTION OF THE DRAWINGS

In order to better understand some embodiments of the invention and to see how it may be carried out in practice, some embodiments are next described, by way of non-limiting examples only, with reference to the accompanying drawings, in which like reference characters denote corresponding features consistently throughout similar embodiments in the attached drawings.

FIGS. 1A and B illustrate top and side views of an electronic device cover.

FIG. 2 shows an electronic device in which a cover has been attached.

FIG. 3 shows a cover being attached to an electronic device with a broken portion.

FIG. 4 shows various illustrations of covers and electronic key fobs.

### DETAILED DESCRIPTION OF THE PREFERRED EMBODIMENT

The following explanation is directed to an electronic device in the form of an electronic key fob as an example; however, any other electronic device can be used as a substrate for the cover, such as an appliance remote or a stationary appliance control panel. Examples of such devices can include mobile or stationary remote keyless entry systems for vehicles or buildings or other doors, remote keyless ignition systems on motor vehicles, remotes for car alarms, garage door openers, computer devices, or computer access keys, wall-mounted home or business alarms, TV remotes, audio and video equipment remotes, stereo system remotes, air conditioning/heating control units, etc.

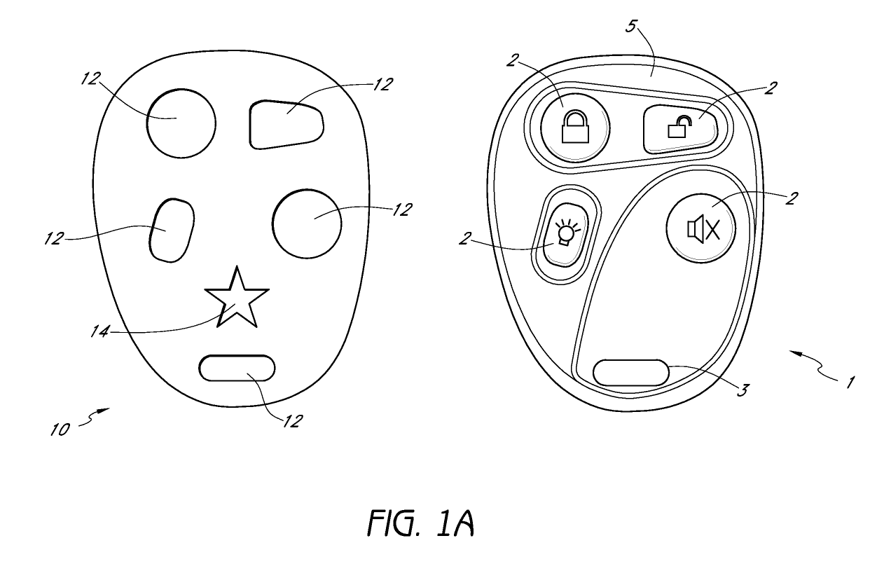

Referring to FIGS. 1A and B, an electronic key fob 1 can have one or more actuators, such as buttons, knobs, or switches; one or more indicators, such as lights or illuminated displays 2; and/or one or more attachment members, such as key rings, lanyards, ropes, or cord attachments 3. The actuators, indicators, and attachment members can be used for performing any number of functions or for conveying, indicating and/or displaying a variety of different information. The attachment member 3 can be used for placing the electronic key fob 1 onto a key ring, chain, lanyard, etc. Some electronic key fobs 1 do not have actuators, displays, and/or attachment members.

The electronic key fob 1 can be contoured and shaped in a particular manner. For example, a vehicle manufacturer can have different electronic key fobs that perform similar or different functions for each model of vehicle, or for each different trim style for a model of vehicle. Some electronic key fobs 1 have a front case or housing 5 and a back case or housing 6. The term “cover” as used herein is intended to used in its ordinary sense, and includes, for example, any case, housing, enclosure, partial enclosure, layer, or other component that obscures and/or protects all or a portion of something. The front 5 and back 6 case can be made of plastic, for example, and can be connected to each other and/or to the underlying electronic device in various ways, such as with a snap fit or with one or more fasteners.

In the illustrated example, the electronic key fob 1 is a remote for a keyless entry system for a vehicle, though the electronic key fob could be any electronic key fob or other type of electronic device as discussed herein or as know in the art, such as, but not limited to: remote keyless entry systems for vehicles or buildings or other doors, remote keyless ignition systems on motor vehicles, remotes for car alarms, garage door openers, computer devices, computer access keys, or any of the other electronic device described herein, etc.

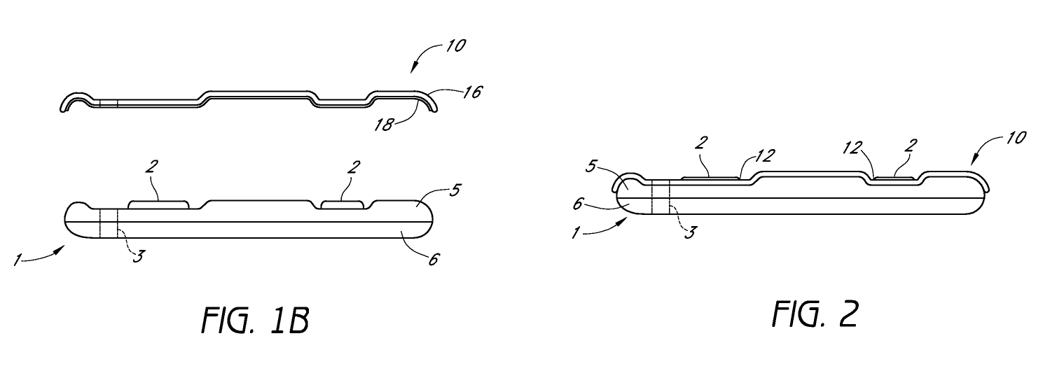

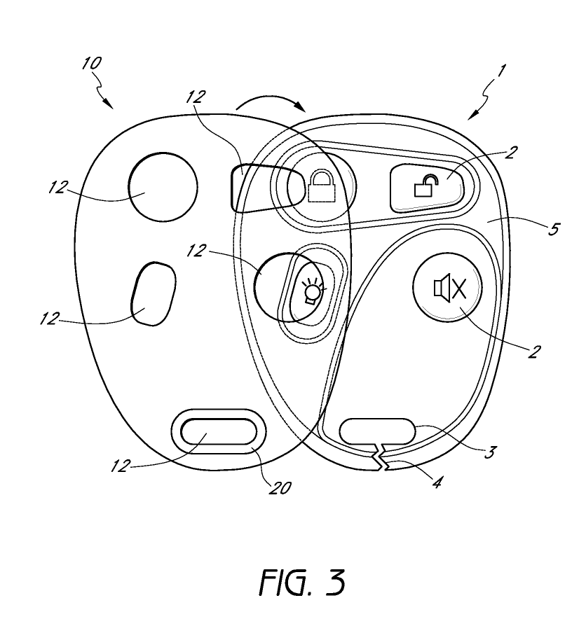

A cover 10 can be attached to the electronic key fob 1. A cover 10 can be attached to either or both of the front case 5 and the back case 6. In some embodiments one cover 10 can be attached to the front case 5 and one cover 10 can be attached to the back case 6. FIGS. 2 and 3 demonstrate how an example of a cover 10 can attach to a front case 5 of an electronic key fob 1. As shown, the cover can attach to the front case 5 while still allowing the front case 5 to be separated from the back case 6 without covering the connection between the two. In some embodiments, the cover 10 can advantageously attach to the key fob while still allowing the key fob to be opened or dismantled, for example, in order to enable replacement of a battery or reprogramming or repair of the underlying key fob.

The cover 10 can give the impression that the electronic key fob 1 is made of a particular material, or have the appearance of a particular material, such as paper, plastic, wood, metal, carbon fiber, fabric, etc., which may be the same as or different from the material of which the underlying original casing or housing of the electronic key fob 1 is actually made. The cover 10 itself, can be made any of a number of materials including paper, plastic, wood, metal, carbon fiber, fabric, etc., and may or may not appear to be made of this material.

In some embodiments, the cover 10 can protect the key fob 1 from breakage or wear. For example, in some embodiments, the cover 10 can protect the key fob from physical contact that may product cracks, chips, scratches, or nicks, or from sunlight, fading, etc. In some embodiments, a cover 10, such as a transparent cover, can be placed over a design feature on the key fob, such as a logo, that the user desires to protect, thereby protecting the design feature.

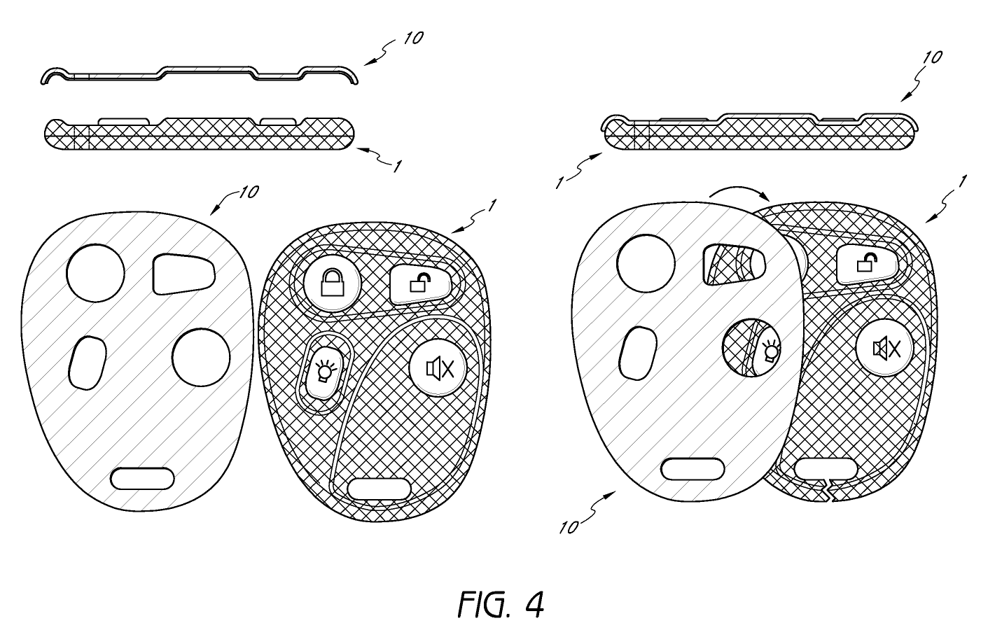

The cover 10 can include a feature 14, such as a picture, logo, design, etc. The feature 14 can be small or large and can cover all of or part of the cover 10. The cover 10 can be any number of colors and textures, including transparent or opaque colors and can add personalized style to the electronic key fob 1. The cover 10 can also be a way of distinguishing or personalizing a set of car keys or a key ring, for example. The cover 10 can change the appearance of the electronic key fob 1. For example, a black and dark grey electronic key fob 1, as shown in FIG. 4 can be changed to a different color represented schematically in the figure.

The cover 10 can also provide a way to increase one's grip on the key fob. Many key fobs are smooth plastic and can be easily dropped or slip from one's hand. The cover 10 can add textures including grooves or ridges to increase friction and decrease the likelihood of dropping the key fob. In some embodiments, the cover 10 can present a rubber or rubber-like surface to increase a user's grip on the key fob.

Returning to FIG. 1B, as shown, the cover 10 can be contoured to match the contours of a particular electronic key fob 1. Advantageously, covers 10 can be designed to match the contours of different electronic key fobs 1. For example, a particular cover can be designed according to the particular shape and contour of a particular key fob for a specific brand and model of vehicle. Also, different or similar style covers 10 can be designed for electronic key fobs 1 for different models and brands of vehicles.

In some embodiments, the bottom of the cover 10 that connects to the key fob can be contoured to match the contours of a particular electronic key fob while the top of the cover can be contoured in a different manner to create a different appearance or shape than that of the original key fob.

In some embodiments, the cover 10 can have an orifice 12. The orifice 12 can allow a feature of the electronic key fob 1 to pass through or show through the cover 10. For example, as can be seen in FIG. 2, a button 2 can pass through an orifice 12. In some embodiments, the orifice 12 can fully or partially surround a feature such as a logo so that the cover 10 does not cover up or hide the logo or design on the electronic key fob 1 itself. In some embodiments, the orifice 12 can be used with the key ring attachment 3. The orifice 12 can surround the key ring attachment 3. The orifice 12 can be used to fully or partially surround any number of different features including: one or more actuators, indicators, and/or attachment members, such as buttons, knobs, switches, displays, lights, speakers, graphics, logos, screw holes, key ring attachments, belt clips, reset button holes, etc.

Still referring to FIG. 1B, the cover 10 can comprise one or more layers 16, 18. The layers can comprise full layers or partial layers. As shown, the cover 10 has a top layer 16 and a bottom layer 18. In some embodiments, the bottom layer comprises an adhesive. In some embodiments, the bottom layer 18 can comprise an attachment member, such as tape, with adhesive on at least a portion of one or both of its upper and lower surfaces. The adhesive can completely cover the back of the top layer 16 or it can cover only parts of the back of the top layer. The adhesive can be used to attach the cover 10 to the electronic key fob 1. In some embodiments, the top layer 16 can comprise a thin piece of plastic. In some embodiments, multiple layers may be used to create a particular design or affect. In some embodiments, a protective layer may be on top of a design layer to protect the design layer or feature 14. In some embodiments, different layers can be used on different parts of the cover 10.

In some embodiments, the cover can comprise at least three layers. The cover can have a base layer of a base material. A top layer can be secured to the base layer. Examples of top layers include a graphics or design layer, a sticker, etc. The bottom layer can be made of a material configured to secure the cover onto the key fob, such as adhesive.

In some embodiments, the cover can be configured to connect to the key fob without adhesive. For example, the cover can be configured to fit snuggly or tightly over the key fob or snap onto the key fob.

Turning now to FIG. 3, the cover 10 can also be used to repair an electronic key fob. For example, some electronic key fobs 1 experience breakage 4 of the key ring attachment 3. A cover 10, according to some embodiments can repair or fix the key ring attachment 3. For example, the cover 10 can comprise a reinforcing section 20. The reinforcing section 20, according to some embodiments, can both close or cover a gap 4 in the key ring attachment 3 and serve as a key ring attachment.

In some embodiments, the reinforcing section 20 can comprise a ring that fully or partially surrounds the key ring attachment 3 of the key fob. In some embodiments, the cover 10 itself can be configured to form the reinforcing section 20. For example, the cover 10 can be made of a material that is sufficiently strong to serve as a key ring attachment. In some embodiments, the reinforcing section 20 can comprise a reinforcing layer.

The reinforcing section 20 can be thicker than one or more other regions of the cover. The reinforcing section can be made from a material different from one or more other regions of the cover. For example, the reinforcing section can be made from a material that is more rigid or less likely to break than one or more other portions of the cover. The reinforcing section can also have generally the same thickness and material as the rest of the cover.

In some embodiments, the reinforcing section 20 can be configured to reinforce and cover at least the thinnest sections of the key fob formed between the key fob and the key ring attachment 3, such as the section near to and generally surround the gap 4 in FIG. 3.

When used with a key ring, the cover 10 can be sufficiently strong so as to prevent ripping or tearing of the cover as the key ring is attached or removed from the key ring attachment 3 when the cover is in place.

As electronic key fobs can be very expensive, a cover with a reinforcing section 20 can provide a low cost way to increase the life of the key fob. For example, to replace an electronic key fob for a vehicle or other electronic device can involve not only the purchase of a new key fob but also the reprogramming of a new key fob, as well as the reprogramming of other older key fobs and keys that are still in use with the same vehicle or other electronic devices. This can greatly increase the cost of replacing a key fob, which can be especially unfortunate when the only problem is that the key ring attachment is broken.

As shown in the figures, the illustrated electronic key fob 1 is a remote for a keyless entry system for a vehicle. However, all of the descriptions regarding covers for key fobs provided herein apply also to any covers for any electronic key fobs and for any covers for any other electronic devices for receiving and/or conveying information, whether mobile or stationary. Examples of such devices include remote keyless entry systems for vehicles or buildings or other doors, remote keyless ignition systems on motor vehicles; remotes for car alarms, garage door openers, computer devices, or computer access keys, wall-mounted home or business alarms; TV remotes, audio and video equipment remotes, stereo system remotes; and air conditioning/heating control units, etc.

Various types of electronic devices can use covers made in accordance with the features, steps, and/or principles described herein. By way of example, a cover can be contoured to fit on the top of a remote control for a home or business air conditioning and heating system. The cover can personalize, or even help hide the remote. The cover can be paintable or otherwise configurable by the user. For example, it may be desirable that the cover match the color of the wall of an interior room.

In some embodiments, a cover for a controller for a home or business air conditioning and heating system control can include one or more layers such as a top layer having a design feature and a bottom layer comprising two-sided tape or adhesive. The cover can include one or more orifices that fully or partially surround various different features on the controller such as: actuators, indicators, and/or attachment members, such as buttons, knobs, switches, displays, lights, speakers, graphics, logos, screw holes, key ring attachments, belt clips, reset button holes, etc.

Although this invention has been disclosed in the context of certain preferred embodiments and examples, it will be understood by those skilled in the art that the present invention extends beyond the specifically disclosed embodiments to other alternative embodiments and/or uses of the invention and obvious modifications and equivalents thereof. In particular, while covers for electronic devices have been described in the context of particularly preferred embodiments, the skilled artisan will appreciate, in view of the present disclosure, that certain advantages, features and aspects of the cover may be realized in a variety of other applications, many of which have been noted above. Additionally, it is contemplated that various aspects and features of the invention described can be practiced separately, combined together, or substituted for one another, and that a variety of combination and sub-combinations of the features and aspects can be made and still fall within the scope of the invention. Thus, it is intended that the scope of the present invention herein disclosed should not be limited by the particular disclosed embodiments described above, but should be determined only by a fair reading of the claims.

The following is claimed:

1. A cover configured for attachment to a remote for an automotive keyless entry system, the cover comprising:
a top surface;
a bottom surface contoured to match the contours of an outer surface of a remote for an automotive keyless entry system;
an adhesive configured to attach the bottom surface to the outer surface of the remote;
at least one orifice passing through the top and bottom surfaces and configured to substantially surround and allow unobstructed access to a button or other feature of the remote; and
a reinforcing section configured to repair and/or reinforce a key ring attachment on the remote.

2. The cover of claim 1, wherein the adhesive comprises two-sided tape.

3. The cover of claim 1, wherein the reinforcing section comprises a reinforcing ring configured to substantially surround one side of the key ring attachment on either the front outer surface or a back outer surface of the remote.

4. The cover of claim 1, wherein the cover is configured to attach to a front outer surface of the remote.

5. The cover of claim 4, wherein the cover is configured to allow a front case and a back case of the remote to be separated without removing or damaging the cover.

6. The cover of claim 4, wherein the cover comprises a front cover and a back cover, the front cover configured to attach to the front outer surface of the remote and the back cover configured to attach to a back outer surface of the remote.

7. The cover of claim 1, further comprising a design feature on the top surface.

8. A cover for use with a remote for an automotive keyless entry system, the cover comprising:
a design layer including a design feature visible to a user;
an adhesive layer configured for attaching the cover to a remote for an automotive keyless entry system; and
a reinforcing layer configured for reinforcing a key ring attachment on the remote;
wherein the cover is contoured to match the contours of an outer surface of the remote for an automotive keyless entry system and configured to attach thereto.

9. The cover of claim 8, further comprising at least one orifice configured to allow access to a button or other feature of the remote.

10. The cover of claim 8, wherein the reinforcing layer comprises a reinforcing ring configured to cover a side of the key ring attachment where the key ring attachment is broken.

11. The cover of claim 8, wherein the reinforcing layer comprises a partial layer.

12. The cover of claim 8, further comprising a protective layer covering the design layer.

13. The cover of claim 8, wherein the design feature comprises at least one of a graphic, logo, picture, symbol, color, and texture.

14. A cover for use with an electronic automotive remote, the cover comprising:
a thin piece of material configured to attach to an electronic automotive remote;
an adhesive configured to secure the thin piece of material to the remote; and
at least one orifice in the thin piece of material, the orifice configured to allow access to a button, key ring attachment or other feature of the remote;
wherein the thin piece of material is shaped to match the contours of the remote to which the cover is configured to attach to.

15. The cover of claim 14, wherein the cover is configured to act as a reinforcing ring to reinforce the key ring attachment on the remote.

16. The cover of claim 14, wherein the adhesive comprises two-sided tape.

17. The cover of claim 14, wherein cover is configured to attach to a front outer surface of the remote.
